(19) United States
(12) Patent Application Publication
(10) Pub. No.: US 2006/0051597 A1
(43) Pub. Date: Mar. 9, 2006

(54) Article coated with titanium compound film, process for producing the article and sputtering target for use in coating the film

(75) Inventors: Toshiaki Anzaki, Osaka (JP); Daisuke Inaoka, Osaka (JP); Yoshifumi Kijima, Osaka (JP)

Correspondence Address: CARRIER BLACKMAN AND ASSOCIATES, 24101 NOVI ROAD, SUITE 100, NOVI, MI, 48375, US

(73) Assignee: Nippon Sheet Glass Co., Ltd., Osaka-shi (JP)

(21) Appl. No.: 10/518,601

(22) PCT Filed: Jun. 17, 2003
(86) PCT No.: PCT/JP03/07688

§ 371 Date: Aug. 15, 2005

(30) Foreign Application Priority Data
Jun. 17, 2002 (JP) 2002-175618

(51) Int. Cl. C23C 14/32; B32B 17/06; B32B 15/04; C23C 14/00

(52) U.S. Cl. 428/432; 204/192.1; 428/457; 204/298.13

(57) ABSTRACT

The present invention provides a method for forming a titanium compound film on a substrate by a sputtering process by use of, in place of a conventional metallic titanium target, a titanium target containing a metal (such as tin or zinc) having two or more times higher sputtering yield in an argon atmosphere than titanium; an article coated with a titanium compound film; and a sputtering target for use in the film coating. The content of tin or zinc in the titanium target containing tin or zinc is preferably in the range of 1 to 45 at %, and further a third metal may be added. These can remove drawbacks in that the film has a low film formation rate and a high output power cannot be applied due to the occurrence of arcing in forming a titanium compound film on the surface of a substrate, such as plate-shaped glass, by a reactive sputtering process.

### TECHNICAL FIELD

The present invention relates to formation of: a titanium compound film, which has photocatalytic activity and is used in all sorts of members such as a windowpane for buildings, a glass plate for display, a glass substrate for DNA analysis, a solar cell, a portable information device, hygienic and medical equipment, electronics, an optical component, a test chip for a biomedical application, an optical fiber for medical endoscopy and surgery, material for hydrogen-oxygen-generating equipment; a powder photocatalytic material; and an optical film material for buildings, automobiles, and communications.

### BACKGROUND ART

Conventionally, when a titanium compound film is prepared, a metallic titanium target is used as a starting material and sputtering is carried out in an oxygen or nitrogen atmosphere, thereby forming a titanium oxide film, a titanium nitride film or a titanium oxide-nitride film.

In the case where a titanium compound film is formed from a metallic titanium target by a conventional method, the film-forming (deposition) rate is low because the sputtering yield of titanium is low and it is hard for the titanium to be sputtered. There was also a problem in that high output cannot be inputted because the target surface reacts with reactive gas to form an insulating film and the surface is electrostatically charged to generate arcing.

As a method for improving the film-forming rate, a method of adding ozone to an inert gas is disclosed in Japanese Patent Laid-Open No. 2001-73116. Further, a method of controlling an oxygen amount by a discharge voltage is proposed in Japanese Patents Laid-Open Nos. 2002-275628 and 2002-322561. However, the film-forming rate has not been improved remarkably even by use of methods proposed in Japanese Patents Laid-Open Nos. 2001-73116, 2002-275628 and 2002-322561.

### DISCLOSURE OF THE INVENTION

To solve the above-mentioned problems, according to the present invention, a titanium compound film was formed on a substrate by a sputtering method by using a titanium target containing a metal having two or more higher sputtering yield in an argon atmosphere than titanium (hereinafter referred to as “metal with a large sputtering yield”) in place of a conventional metallic titanium target. By using the titanium target containing the metal with a large sputtering yield, it is possible to secure a larger film-forming (deposition) rate than in using the conventional metallic titanium target.

The sputtering yield is the percentage of the number of atoms sputtered per incident ion. (Pages 68-85 of a first edition of a book entitled “Thin-Film Technology” written by HAYAKAWA Shigeru and WASA Kiyotaka in 1982, Kyoritsu Publishing Co., Ltd.). A material with a large sputtering yield shows a large film formation rate by sputtering. The sputtering yield varies with a target material with reference to the same incident ion, wherein the less the surface bonding energy of the material, the larger the sputtering yield. Namely, the sputtering yield varies with the material and in general, an easily sputtered material shows a larger sputtering yield. Thus, the sputtering yield can be an indicator of ease of sputtering the material.

However, to use the sputtering yield as the indicator, it is necessary to use the sputtering yield measured by the same device and in the same conditions. The value measured by the same device and in the same conditions becomes a meaningful value as the indicator of ease of sputtering, but it is not so meaningful to make a comparison between sputtering yields measured by different device and under different conditions. In other words, the sputtering yield varies with the measuring method and the measuring condition and even the sputtering yield of the same material varies greatly. It is therefore wise not to use the values of the sputtering yields of materials obtained from different experiments as the indicator of ease of sputtering.

According to the present invention, the ratio of sputtering yields between a metal with a large sputtering yield and titanium means the ratio of the measured value of sputtering yields between the metal and the titanium measured in the same condition in an argon atmosphere. The ratio is used as a factor for showing the ratio of ease of sputtering the metal with a large sputtering yield and the titanium in the same condition. The sputtering yield varies with the energy of an argon ion, but in the present invention, the sputtering yield relative to the argon having an energy range used on the actual sputtering film-formation is used. For example, the sputtering yield relative to argon having energy in the range of 200 to 700 eV is favorably used. In the case of measuring the sputtering yield, it is desirable that other sputtering conditions are the same as the actual film-formation conditions.

A measuring method for the sputtering yield is not particularly limited. However, the same method measured by a group in which Wehner plays a central part [e.g., N. Laegreid and G. K. Wehner, J. Appl. Phys., 32, 365 (1961) and D. Rosenberg and G. W. Wehner, J. Appl. Phys., 33, 1842 (1962)] can be used.

In the present invention, a film-formation rate in an argon atmosphere may also be used in place of the sputtering yield. When the sputtering yield is large, the film formation rate has a tendency to be large. Accordingly, it is also possible to express the present invention using the deposition rate as a parameter. The deposition rate of each metal also uses the value measured in the same condition as in the actual film formation in the same manner as the sputtering yield.

In the present invention, the titanium target containing the metal of which the sputtering yield in an argon atmosphere is more than twice that of titanium (i.e., the metal with a large sputtering yield) is used. The metal is sputtered prior to the titanium in during sputtering and as a result, the texture of the target surface becomes rough, and an exposed surface area increases. In this manner, subsequent sputtering of titanium is accelerated and the deposition rate of the titanium target becomes large as a whole. However, such a remarkable effect is observed in a practical production process, when the content of the metal in the titanium compound film is 1 to 45 at % (metal conversion).

When the metal content less than 1 at % is not suitable because an effect of increasing the film formation rate by the metal is not recognized so much at the same time, the metal content more than 45 at % is not suitable because the crystal structure of the titanium compound becomes disordered and recombination centers occur, whereby photocatalytic activity is deteriorated in the use as a photocatalyst for example.

Further, the desirable metal content is 1 to 20 at %. The metal content more than 20 at % is not suitable because durability tends to decrease. For example, when the zinc content is more than 20 at %, it reacts with water under irradiation of light and a zinc oxide itself is decomposed to reduce the durability of a film.

The composition of a sputtering target is also to be within the similar range for the reason mentioned above.

Although the metal with a large sputtering yield included in the target is contained in the titanium compound film formed in the sputtering process, the metal, if the amount thereof is small, does not represent a large inhibitory factor to the function of interest. Accordingly, a titanium compound film containing a small amount of the metal with a large sputtering yield can be formed on the substrate. Further, when the metal with a large sputtering yield does not so much affect the characteristic (such as an optical function) exhibited by the formed titanium compound film, desired characteristics can be utilized even if the metal is included to a certain degree.

To separate the metal with a large sputtering yield included in the titanium compound film from the titanium compound, it is sometimes effective to heat the metal during and/or after film formation. By way of such heat-treatment (e.g., in vacuum, at 300° C., for one hour), it is possible to somewhat separate a composition phase of the titanium compound such as a titanium oxide from a phase of the metallic compound such as the metal oxide in some cases.

Referring to a use whereby the metal with a large sputtering yield in the film is caused to effectively function (e.g., the application whereby the metal in the film is used as an acceptor, that is a hole release source to enhance photocatalytic activity), it is not necessary to make such separation actively. By adjusting the degree of separation, the amount of the metal with a large sputtering yield can also be arbitrarily adjusted.

Used as the titanium target are a solid solution of titanium and the metal, a mixture of titanium and the metal, a compound of titanium and the metal, and a combination thereof, etc. The target used in the present invention is not necessarily produced by any specific production method, but can be produced by a well-known method. For example, a method for sintering raw powder of titanium and the metal in a non-oxidizing atmosphere (a powder sintering method and a sintering fusion method), a method whereby raw material is atomized in plasma or arc to be deposited on a substrate (a thermal spraying or sputtering method), etc. are proposed.

By performing sputtering in the presence of a reactive gas such as oxygen, nitrogen, hydrogen and water using a sputtering target containing the metal with a large sputtering yield according to the present invention, it is possible to obtain a titanium compound film such as titanium oxide, titanium nitride and titanium oxide-nitride at a high film formation rate. The film formation rate becomes 2-15 times higher than in the conventional titanium metallic target and thus productivity remarkably improves compared to the conventional method.

Further, the titanium target containing the metal according to the present invention may contain 5 to 50 at % of niobium or tantalum, thereby preventing columnar structure or crystal growth of the titanium compound film. In this manner, when niobium or tantalum is added into the titanium compound film and columnar structure or crystal growth is prevented, the film minimizes light scattering and exhibits excellent performances as an optical film for communications.

Furthermore, a titanium compound film with a high photocatalytic activity can be obtained at a high film formation rate by allowing the film to contain 0.01 to 10 at % of at least one metal of iron and molybdenum in the titanium target containing the metal according to the present invention.

When the titanium compound film is used as a photocatalytic material, the photocatalytic activity of the titanium compound film can be further enhanced by providing a crystal metal oxide layer between the substrate and titanium compound film. As the metal oxide layer, a zirconium oxide layer, a zinc oxide layer, a magnesium oxide layer, a tin oxide layer, or an iron oxide layer is preferably used. When these crystal metal oxide layers are used as an undercoat film of the titanium compound film, the crystallinity of the titanium compound film is enhanced, which is formed on these layers by a reactive sputtering method by use of the titanium target containing the metal, resulting in further better photocatalytic activity.

The substrate for forming the titanium compound film can be any material which does not suffer damage in the case of sputtering deposition, such as plate-shaped glass, plate-shaped resin, a glass block, plate-shaped ceramic, cloth-shaped glass fiber. However, a plate-shaped glass such as a soda-lime silica glass, a soda-lime silica glass on which a metallic oxide layer is formed, and a silica glass is particularly suitable from the viewpoint of durability and maintenance of functionality. If the above-mentioned production method is combined with a mass separation method or an evaporation method in gas, fine photocatalytic particles can also be formed at a high speed.

As a metal with a large sputtering yield in the present invention, tin, zinc, nickel, iron and indium are preferably used, and tin and zinc having a large effect for improving a film-forming rate are more preferably used.

Further, when any of tin, zinc and indium or a plurality of metals selected therefrom are used, these metals oxidized in a sputtering process exhibit electrical conductivity, and thus the electrostatic charge on the target surface and arcing due to the charge are controlled. This enables the application of high electric power to the target, realizing a large deposition rate. Thus, tin, zinc and indium are preferably used as the metal with a large sputtering yield.

When tin or zinc is used as a metal with a large sputtering yield, a crystallization improvement effect of a titanium compound film obtained by film formation is observed and the film has excellent crystallization even by film formation at a low temperature, thereby obtaining a titanium compound film having a high photocatalytic activity. Such crystallization improvement effect is recognized when the content of tin or zinc in the titanium compound film is 1 to 45 at %.

However, for members such as the above-mentioned optical film for industrial use with acid resistance emphasized, except photocatalysts, functions such as photocatalytic activity or durability. Such as acid resistance are deteriorated when a large amount of tin or zinc is added as mentioned above. Thus, it is preferable that the amount tin or zinc to be added is not greater than 20 at %.

Further, when the target has a high density, the film after film formation also has a high density. Thus, if the target density is increased by calcination or the like, a rigid film with a high density can be formed, improving functions and durability. Since a target of the present invention has a large film formation rate, a practical film formation rate can be secured even when allowing the film to have a high density. However, when an ordinary target has a high density, the film formation rate decreases, so that the production substantially becomes difficult.

### BRIEF DESCRIPTION OF THE DRAWINGS

FIGS. 1 and 2 show x-ray diffraction patterns of TiO₂ and TiSnₓO_{y}.

### BEST MODE FOR CARRYING OUT THE INVENTION

### EXAMPLES 1 TO 9 AND COMPARATIVE EXAMPLES 1 TO 3

Various targets each having a size of 15 inches×5 inches, shown in Table 1 were mounted on a magnetron sputtering device which has a distance of 65 mm between a substrate position and a target. A titanium compound film was deposited at a target input power of 3 kW while conveying various substrates (100-mm-square, 3-mm-thickness) at a constant speed (1 m/min) under the conditions shown in Table 1. A process for passing the substrate was repeated given number of times (i.e., given pass number of times), and thereby a titanium compound film with a given thickness was deposited.

The film thickness of a titanium compound film was obtained by measuring a step between a non-deposited section and a deposited section using a stylus-type thickness-meter (DecktackIID made by Sloan Company).

The deposition rate (dynamic rate) was calculated by the thickness of a film deposited on a substrate when passing once below the target at a conveyance speed of 1 m/min in the deposition output of 1 kW. The following formula was used for calculation.
Deposition rate=film thickness×conveyance speed÷(deposition pass number of times×target input power)

Further, for the purpose of examining the impact of a crystalline primary film of the titanium compound film, crystallinity of the thin film was evaluated by using X-ray diffractometry for thin film.

The measured data of film thickness, deposition rate and analysis results on crystallinity by X-ray diffraction are shown in Table 1.

As Comparative Examples, titanium compound films were formed under the conditions shown in Table 2 by using the same sputtering device as above except that a metallic titanium target was used instead. These Comparative Examples were also measured in terms of the same items as Examples, and the obtained data are summarized in Table 2.

TABLE 1

| | Example 1 | Example 2 | Example 3 | Example 4 | Example 5 |
|---|---|---|---|---|---|
| Film composition | TiZnOxide | TiZnOxide | TiZnOxide | TiZnOxide | TiZnNbOxide |
| Substrate | Soda-lime | Glass with | Soda-lime | Soda-lime | Soda-lime |
| | glass | ZrO₂ film | glass | glass | glass |
| Target (figure | 90Ti—10Zn | 80Ti—20Zn | 90Ti—10Zn | 90Ti—10Zn | 60Ti—10Zn—30Nb |
| indicates a molar | | | | | |
| ratio) | | | | | |
| Sputtering gas | Ar:O₂ = 50:50 | Ar:O₂ = 50:50 | Ar:O₂ = 50:50 | Ar:O₂ = 50:50 | Ar:O₂ = 50:50 |
| composition | | | | | |
| Sputtering gas | 0.4 | 0.4 | 0.4 | 0.4 | 0.4 |
| pressure (Pa) | | | | | |
| Treatment after | — | — | Later | — | — |
| film formation | | | calcination | | |
| Film thickness | 50 | 100 | 250 | 500 | 300 |
| (nm) | | | | | |
| Film formation rate | 3.5 | 9.8 | 3.5 | 3.5 | 3.4 |
| [nm · m/ | | | | | |
| (min · kW)] | | | | | |
| X-ray diffraction | Amorphous | Crystalline | Crystalline | Amorphous | Amorphous |
| analysis | | | | | |
| (Ti compound) | | | | | |

| | Example 6 | Example 7 | Example 8 | Example 9 |
|---|---|---|---|---|
| Film composition | TiZnOxide | TiZnOxide | TiZnOxide:Fe | TiZnOxide |
| Substrate | Glass with | Glass with | Glass with | Soda-lime |
| | ZnO film | MgO film | ZrO₂ film | glass |
| Target (figure | 60Ti—40Zn | 80Ti—20Zn | 90Ti—9.8Zn:Fe0.2% | 99Ti—1Zn |
| indicates a molar | | | | |
| ratio) | | | | |
| Sputtering gas | Ar:O₂ = 50:50 | Ar:O₂ = 50:50 | Ar:O₂ = 50:50 | Ar:0₂ = 50:50 |
| composition | | | | |
| Sputtering gas | 0.4 | 0.4 | 0.4 | 0.4 |
| pressure (Pa) | | | | |
| Treatment after | — | — | — | — |
| film formation | | | | |
| Film thickness | 50 | 100 | 50 | 100 |
| (nm) | | | | |
| Film formation rate | 12.3 | 9.8 | 3.4 | 1.2 |
| [nm · m/(min · kW)] | | | | |
| X-ray diffraction | Crystalline | Crystalline | Crystalline | Amorphous |
| analysis (Ti | | | | |
| compound) | | | | |

TABLE 2

| | Comparative | Comparative | Comparative |
|---|---|---|---|
| | Example 1 | Example 2 | Example 3 |
| Film composition | TiO₂ | TiO₂ | 70TiO₂—15Nb₂O₂ |
| Substrate | Soda-lime glass | Glass with | Soda-lime glass |
| | | ZrO₂ film | |
| Target (figure | Ti (four nines) | Ti (four nines) | 70Ti—30Nb |
| indicates a | | | |
| molar ratio) | | | |
| Sputtering gas | Ar:O₂ = 50:50 | Ar:O₂ = 50:50 | Ar:O₂ = 50:50 |
| composition | | | |
| Sputtering gas | 0.4 | 0.4 | 0.4 |
| pressure (Pa) | | | |
| Treatment after | — | — | — |
| film formation | | | |
| Film thickness | 500 | 100 | 300 |
| (nm) | | | |
| Film formation | 0.8 | 0.8 | 1 |
| rate [nm · m/ | | | |
| (min · kW)] | | | |
| X-ray diffraction | Amorphous | Crystalline | Amorphous |
| analysis | | | |

The sputtering yields of these metals were measured using hot-cathode discharge according to the procedures described in papers [(G. K. Wehner, Phys. Rev., 102, p690 (1956) or G. K. Wehner, Phys. Rev., 108, p35 (1957)] written by Wehner et al. A target of a metal (atomic weight M) to be measured was prepared, and the mass thereof was measured in advance. The target was first installed in a device and then, an exhaust velocity was adjusted to have a gas pressure of 3 mTorr while introducing argon gas. Thereafter, a potential difference of 400V was applied between an anode and a cathode and electricity was discharged for 1 hour (3,600 seconds) while recording ion current I (unit A). After discharge, mass defect ΔW (unit g) of the target was measured by an electrobalance, and the sputtering yield S was obtained by the following calculation formula.
S=(ΔW×N_{A}×e)/(M×I×3600)
wherein N_{A} is Avogadro's number (=6.022×10²³/mol), e is an elementary electric charge (=1.602×10⁻¹⁹ C).

The sputtering yields of titanium, zinc, tin and niobium were measured according to the above-described method. As a result, they had a yield of 0.4, 2.6, 3.0 and 0.5, respectively. Namely, the sputtering yield of zinc was 6.5 times higher than that of titanium, the sputtering yield of tin was 7.5 times higher and the sputtering yield of niobium was 1.25 times higher than that of titanium.

In addition, the deposition rates of these metals were measured according to the following procedures. A deposition device SCH-3030 available from ULVAC, Inc. was used. A metallic target having a size of 20×5 inches was used, the deposition output was fixed at 1 kW, and then two pass depositions were carried out at a conveyance speed of 1 m/min in an argon atmosphere at 0.4 Pa. A step between a deposited section and a non-deposited section was measured using the stylus-type thickness-meter and the deposition rate was calculated using the numerical formula described above.

The deposition rates of titanium, zinc, tin and niobium were calculated, and consequently, they were 8.4, 41, 66 and 15 nm m/min, respectively. Namely, zinc had about 4.9 times higher deposition rate than titanium, tin had about 7.9 times higher and niobium had about 1.8 times higher deposition rate than titanium.

In Examples 1 to 9, titanium targets containing zinc having two or more times higher sputtering yield and film formation rate than titanium were used for film formation, and the film formation rates of titanium compound films thereof were larger than those of Comparative Examples 1 and 2 wherein metallic titanium targets were used for film formation, and that of Comparative Example 3 wherein film formation was carried out using a titanium target containing niobium having less than two times higher sputtering yield and film formation rate than titanium. Some Examples had about 15 times the figures, and improvement of film formation efficiency was observed. Further, even when titanium targets containing zinc to which metals described in Examples 5 and 8 are added or doped are used, it is obvious that a high film formation rate is kept.

### EXAMPLES 10 TO 20 AND COMPARATIVE EXAMPLES 4 TO 5

Various targets each having a size of 15 inches×5 inches, shown in Table 1 were mounted on a magnetron sputtering device which has a distance of 65 mm between a substrate position and a target. A titanium compound film was deposited at a target input power of 3 kW while conveying various substrates (100-mm-square, 3-mm-thickness) at a constant speed (1 m/min) under the conditions shown in Table 3. A process for passing the substrate was repeated given number of times (i.e., given pass number of times), and thereby a titanium compound film with a given thickness was deposited.

The thickness of a titanium compound film, film formation rate, crystallinity of a thin film, and sputtering yield were measured or observed in the same manner as those in the above Examples. It should be noted that the reason for large difference in film formation rate between Examples 1 to 9 and Examples 10 to 20 even under almost the same conditions is that film formation rate largely depends upon a device to be used. In other words, when the magnetic field density becomes low due to change of a film formation device, the ion density in a plasma decreases and oxidized film formation on the target surface proceeds. As a result, the rate of the titanium target decreases. Whatever device is used, the film formation rate is improved when a target having other metal mixed with titanium at a predetermined ratio is used rather than metallic titanium only.

In Comparative Examples 4 and 5, the same sputtering device was used as in Examples 10 to 20 except that metallic titanium targets were used. Under the condition described in Table 4, the formation of a titanium compound film was carried out. The obtained data is shown in Table 4.

Tables 3 and 4 describe a pure water contact angle after 60-min UV irradiation (UV responsive hydrophilicity) and a contact angle after 7-day storage in a dark place (hydrophilic maintenance in a dark place), and experimental conditions therefor are as follows.

1) UV Responsive Hydrophilicity

A sample was irradiated with ultraviolet light (light source: black light, lighting intensity: 1 mW/cm²), and then a droplet contact angle was measured for evaluation. It can be said that a smaller droplet contact angle immediately after ultraviolet irradiation means a better UV responsive hydrophilicity.

2) Hydrophilic Maintenance Property in a Dark Place

Ultraviolet light (light source: low-pressure mercury vapor lamp, irradiation time: 10 min, lighting intensity: 254 nm, emission line: −11.0 mW/cm², 365 nm, emission line: −4.0 mW/cm²) was applied to super-hydrophilize a sample so that a film surface thereof had a droplet contact angle (θ) of less than 5°. Next, the sample was placed and held in a dark place for 7 days and thereafter a droplet contact angle was measured. It can be said that a smaller droplet contact angle after 7-day storage in a dark place means a better hydrophilic maintenance property.

TABLE 3

| | Example 10 | Example 11 | Example 12 | Example 13 | Example 14 | Example 15 |
|---|---|---|---|---|---|---|
| Film composition | TiZnOxide | TiZnOxide. | TiZnOxide | TiSnZnOxide | TiZnOxide | TiZnOxide |
| Substrate | Glass with ZrO₂ | Glass with ZrO₂ | Soda-lime glass | Glass with | Glass with ZnO | Glass with MgO |
| | film | film | | ZrO₂ film | film | film |
| Target (figure indicates | 90Ti—10Zn | 80Ti—20Zn | 90Ti—10Zn | 70Ti—20Sn—10Zn | 60Ti—40Zn | 80Ti—20Zn |
| a molar ratio) | | | | | | |
| Sputtering gas | Ar:O₂ = 50:50 | Ar:O₂ = 50:50 | Ar:O₂ = 50:50 | Ar:O₂ = 50:50 | Ar:O₂ = 50:50 | Ar:O₂ = 50:50 |
| composition | | | | | | |
| Sputtering gas | 0.4 | 0.4 | 0.4 | 0.4 | 0.4 | 0.4 |
| pressure (Pa) | | | | | | |
| Treatment after | — | — | Later | — | — | — |
| film formation | | | calcination | | | |
| Film thickness (nm) | 50 | 50 | 50 | 50 | 50 | 50 |
| Film formation rate | 1 | 1.5 | 1 | 2.1 | 2.1 | 1.5 |
| [nm · m/(min · kW)] | | | | | | |
| X-ray diffraction analysis | Crystalline | Crystalline | Crystalline | Crystalline | Crystalline | Crystalline |
| (titanium compound) | | | | | | |
| Droplet contact angle | 25° | 38° | 27° | 25° | 39° | 39° |
| after 60-min UV | | | | | | |
| irradiation | | | | | | |
| Droplet contact angle | 29° | 34° | 31° | 23° | 39° | 38° |
| after super- | | | | | | |
| hydrophilization | | | | | | |
| (θ < 5°) | | | | | | |
| and leaving in a dark | | | | | | |
| place for 7 days | | | | | | |

| | Example 16 | Example 17 | Example 18 | Example 19 | Example 20 |
|---|---|---|---|---|---|
| Film composition | TiZnOxide:Fe | TiSnOxide | TiSnOxide | TiSnOxide | TiSnOxide |
| Substrate | Glass with ZrO₂ | Glass with ZrO₂ | Glass with ZrO₂ | Glass with | Glass with ZrO₂ |
| | film | film | film | ZrO₂ film | film |
| Target (figure indicates a molar | 90Ti—9.8Zn:FeO.2% | 90T Ti—10Sn | 80Ti—20Sn | 70Ti—30Sn | 55Ti—45Sn |
| ratio) | | | | | |
| Sputtering gas composition | Ar:O₂ = 50:50 | Ar:O₂ = 50:50 | Ar:O₂ = 50:50 | Ar:O₂ = 50:50 | Ar:O₂ = 50:50 |
| Sputtering gas pressure (Pa) | 0.4 | 0.4 | 0.4 | 0.4 | 0.4 |
| Treatment after film formation | — | — | — | — | — |
| Film thickness (nm) | 50 | 50 | 50 | 50 | 50 |
| Film formation rate | 1 | 1.4 | 1.6 | 2.5 | 3.6 |
| [nm · m/(min · kW)] | | | | | |
| X-ray diffraction analysis | Crystalline | Crystalline | Crystalline | Crystalline | Crystalline |
| (titanium compound) | | | | | |
| Droplet contact angle after | 23° | 7° | 10° | 33° | 38° |
| 60-min UV irradiation | | | | | |
| Droplet contact angle after | 28° | 14° | 12° | 13° | 13° |
| super-hydrophilization (θ < 5°) | | | | | |
| and leaving in a dark place for 7 | | | | | |
| days | | | | | |

TABLE 4

| | Comparative | Comparative |
|---|---|---|
| | Example 4 | Example 5 |
| Film composition | TiO₂ | TiO₂ |
| Substrate | Soda-lime glass | Glass with ZrO₂ film |
| Target (figure indicates a molar | Ti (four nines) | Ti (four nines) |
| ratio) | | |
| Sputtering gas composition | Ar:O₂ = 50:50 | Ar:O₂ = 50:50 |
| Sputtering gas pressure (Pa) | 0.4 | 0.4 |
| Treatment after film formation | — | — |
| Film thickness (nm) | 50 | 50 |
| Film formation rate | 0.8 | 0.8 |
| [nm · m/(min · kW)] | | |
| X-ray diffraction analysis | Amorphous | Crystalline |
| Droplet contact angle after | 26 | 11 |
| 60-min UV irradiation | | |
| Droplet contact angle after | 40° | 26° |
| super-hydrophilization (θ < 5°) | | |
| and leaving in a dark place for 7 | | |
| days | | |

In Examples 17 to 20, when targets having an Sn content of 10 to 45 at % were used, it was revealed that a hydrophilic maintenance function in a dark place was accelerated.

In the Examples, plate-shaped glass was shown as a substrate, but the present invention is also applicable to a plate-shape resin, a glass block, plate-shaped ceramic, cloth-shaped glass fiber, and the like.

The following Table 5 shows the proportions of Sn in a target, film formation rates, UV responsive hydrophilicity of deposited and laminated films, and hydrophilic maintenance in a dark place. According to the table, it is clear that increase of Sn ratio improves a film formation rate, but UV responsive hydrophilicity deteriorates. It is understood that Addition of Sn, regardless of the addition amount thereof, has enhanced hydrophilic maintenance in a dark place. Laminated films of Table 5 were formed using a sputtering device described in Examples 10 to 20, and the films were composed of a glass substrate/SiO2 (10 nm thickness)/ZrO₂ (25 nm thickness)/TiSₙO_{y} (50 nm thickness). Among these, TiSnₓO_{y} film was formed by sputtering in an argon-oxygen (50:50) at a pressure of 0.4 Pa, using the target described in Table 5. UV responsive hydrophilicity or hydrophilic maintenance in a dark place were measured under the same conditions as those for Tables 3 and 4

TABLE 5

| | | | UV response | | | Hydrophilic | | |
|---|---|---|---|---|---|---|---|---|
| | | | hydrophilicity | | | maintenance in a | | |
| | Ratio of film | | | UV | | dark place | | |
| | formation rate | | Before | irradiation | | After | 7 days | |
| Target | (vs. Ti target) | | irradiation | for 60 min | | initialization | later | |
| Ref.) Ti | 1.0 time | | 49° | 11° | | 4° | 26° | |
| \textcircled{1} Ti—Sn (2at %) | 1.2 times | Δ | 43° | 8° | Δ | 3° | 17° | ◯ |
| \textcircled{2} Ti—Sn (9.2at %) | 1.7 times | ◯ | 36° | 7° | Δ | 3° | 14° | ⊚ |
| \textcircled{3} Ti—Sn (20at %) | 1.9 times | ◯ | 33° | 10° | Δ | 2° | 12° | ⊚ |
| \textcircled{4} Ti—Sn (30at %) | 3.1 times | ⊚ | 41° | 33° | X | 2° | 13° | ⊚ |
| \textcircled{5} Ti—Sn (40at %) | 4.2 times | ⊚ | 41° | 37° | X | 2° | 13° | ⊚ |

Compared with Ti target film formation:

| | | |
|---|---|---|
| | ⊚: | Pretty superior |
| | ◯: | Superior |
| {open oversize bracket} | Δ: | Same level |
| | X: | Inferior |

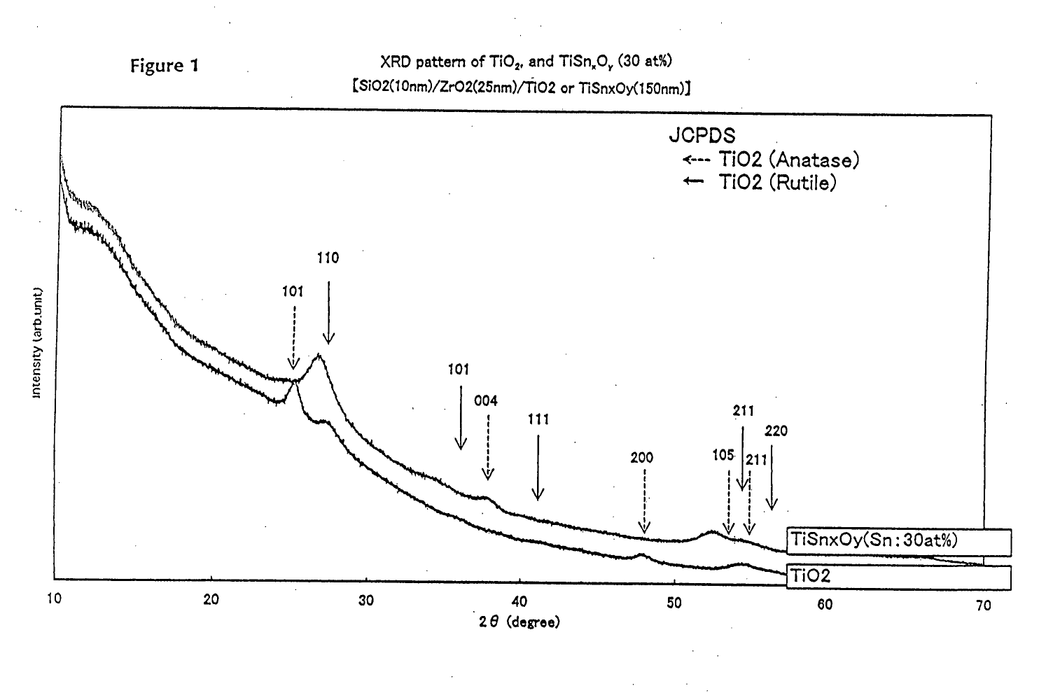

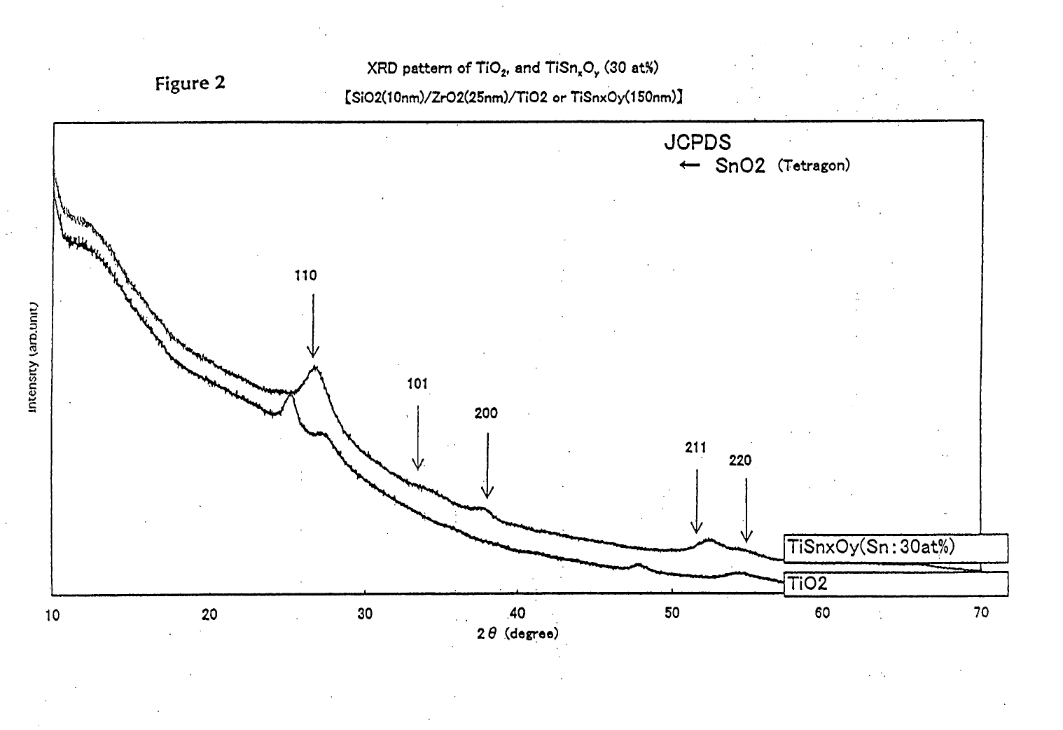

Further, FIGS. 1 and 2 show the same data, but these two figures are separately used for easily referring JCPDS data. According to these figures, it is considered that the crystal structure of TiSnₓO_{y} (Sn: 30 at %) is an SnO₂ tetragon or similar to a TiO₂ rutile crystal structure.

### INDUSTRIAL APPLICABILITY

According to the present invention, a titanium compound film is formed using a titanium target containing tin or zinc by a reactive sputtering method, which can increase a film formation rate and reduce a production cost. Further, use of a titanium target containing tin or zinc enables obtainment of a titanium compound film with enhanced optical characteristics and photocatalytic activities while maintaining the film formation rate. In particular, when tin is selected as a metal to be added, it is possible to obtain a thin film having an excellent hydrophilic maintenance function in a dark place as well as an improved film forming rate.

1. A method for producing an article coated with a titanium compound film characterized in that a titanium target containing 1 to less than or equal to 45 at % of a metal with two or more times higher sputtering yield than that of titanium in an argon atmosphere is used in forming the titanium compound film on a substrate by a reactive sputtering process.

2. The method for producing an article coated with a titanium compound film according to claim 1, wherein the titanium target contains 1 to 20 at % of the metal with two or more times higher sputtering yield than that of titanium in an argon atmosphere.

3. The method for producing an article coated with a titanium compound film according to claim 1, characterized in that the titanium target containing the metal contains a third metal other than titanium and the metal.

4. The method for producing an article coated with a titanium compound film according to claim 3, characterized in that the third metal comprises at least one of iron and molybdenum.

5. The method for producing an article coated with a titanium compound film according to claim 3, characterized in that the titanium target contains 0.01 to 10 at % of the third metal.

6. The method for producing an article coated with a titanium compound film according to claim 1, further comprising a step of conducting heat treatment during and/or after film formation of the titanium compound film.

7. The method for producing an article coated with a titanium compound film according to claim 1, characterized in that the titanium compound is a titanium oxide.

8. The method for producing an article coated with a titanium compound film according to claim 1, characterized in that the titanium compound is a titanium nitride.

9. The method for producing an article coated with a titanium compound film according to claim 1, characterized in that a substrate coated with the film is a plate-shaped glass.

10. The method for producing an article coated with a titanium compound film according to claim 1, characterized in that the metal is tin.

11. The method for producing an article coated with a titanium compound film according to claim 1, characterized in that the metal is zinc.

12. An article coated with a titanium compound film having a photocatalytic function or an optical function, produced by the method according to claim 1.

13. The article coated with a titanium compound film having a photocatalytic function according to claim 12, characterized in that a crystalline zirconium oxide layer, a zinc oxide layer, a magnesium oxide layer, a tin oxide layer, or an iron oxide layer is provided between the substrate and the titanium compound film.

14. An article coated with a titanium compound film containing a metal, wherein the metal has two or more times higher sputtering yield in an argon atmosphere than that of titanium and the metal content ratio of the metal to titanium is 1 to less than or equal to 45 at %.

15. The article coated with a titanium compound film according to claim 14, wherein the metal content ratio of the metal to titanium is 1 to 20 at %.

16. The article coated with a titanium compound film according to claim 14, wherein the metal is tin.

17. The article coated with a titanium compound film according to claim 14, wherein the metal is zinc.

18. The article coated with a titanium compound film according to claim 14, characterized in that the titanium compound is titanium oxide.

19. The article coated with a titanium compound film according to claim 14, characterized in that a substrate of the article is plate-shaped glass.

20. A titanium target containing a metal, which is used for forming a titanium compound film on a substrate by a reactive sputtering process, characterized in that the metal has two or more times higher sputtering yield in an argon atmosphere than titanium and the metal content ratio of the metal to titanium is 1 to less than or equal to 45 at %.

21. The titanium target containing a metal according to claim 20, wherein the metal content ratio of the metal to titanium is 1 to 20 at %.

22. The titanium target containing a metal according to claim 20, characterized in that a third metal other than the titanium and the metal is contained in the titanium target containing the metal.

23. The titanium target containing a metal according to claim 22, characterized in that the content of the third metal is 0.01 to 10 at %.

24. The titanium target containing a metal according to claim 22, characterized in that the third metal is at least one of iron and molybdenum.

25. The titanium target containing a metal according to claim 20, wherein the metal is tin.

26. The titanium target containing a metal according to claim 20, wherein the metal is zinc.
